(19) United States
(12) Patent Application Publication
(10) Pub. No.: US 2026/0079408 A1
(43) Pub. Date: Mar. 19, 2026

(54) METHODS OF PERFORMING 3D METROLOGY ON A STRUCTURE

(71) Applicant: KLA CORPORATION, Milpitas, CA (US)

(72) Inventors: Li WANG, Alamo, CA (US); Miao WANG, Shanghai (CN); Yukun SUN, Canton, MI (US); Da LI, Ann Arbor, MI (US)

(21) Appl. No.: 18/884,896

(22) Filed: Sep. 13, 2024

(51) Int. Cl. G03F 7/00

(52) U.S. Cl. CPC G03F 7/70625; G03F 7/70655; G03F 7/706833; G03F 7/706849

(57) ABSTRACT

A method of performing 3D metrology on a structure includes directing an electron beam onto a surface of the structure, capturing a first set of images of the structure at a first landing angle, capturing a second set of images of the structure at a second landing angle, the second landing angle being different from the first landing angle, and determining, by comparing the first set of images to the second set of images, at least one 3D parameter of the structure. The first set of images at the first landing angle and the second set of images at the second landing angle are captured in a single run of the electron beam across the surface of the structure.

### FIELD OF THE INVENTION

The embodiments described herein relate to methods of performing 3D metrology and, more specifically, to methods of performing 3D metrology on high aspect ratio structures.

### BACKGROUND

In the semiconductor manufacturing industry, maintaining the pace of Moore's Law has become increasingly challenging. Modern three-dimensional (“3D”) semiconductor structures, such as 3D NAND devices, now frequently feature over 200 layers. As these structures become increasingly complex, a need exists for precise metrology solutions that can accurately measure horizontal and vertical dimensions of these structures, along with other relevant 3D features.

However, current metrology tools face limitations in meeting these demands. For example, Optical Critical Dimension (“OCD”) tools are hindered by their large spot sizes, which restrict their use to repeating patterns on a structure (e.g., semiconductor) surface. Electron beam metrology tools offer good alternatives as they have advantages with much smaller spot sizes, high resolution and direct images. In order to derive 3D measurements using these electron beam metrology tools, the landing angle of the electron beam must be changed multiple times to capture images of the structure at various angles. But a traditional electron beam metrology tool's landing angle is fixed within a single metrology test. As a result, the tool needs to change the landing angle after finishing the first measurement test before starting the second measurement test in order to achieve the goal of obtaining images under different landing angles. This approach is both time-consuming and error-prone, making it difficult to complete 3D metrology in a single job run. Furthermore, the repeated adjustment of the electron beam may lead to inconsistencies in measurements, which may further complicate the process of obtaining accurate 3D parameters. Accordingly, a need exists for a method of performing 3D metrology on a structure that ensures accurate and consistent 3D measurements using two or more landing angles in a single job run.

### SUMMARY OF THE DISCLOSURE

In an embodiment of the present disclosure, a method of performing 3D metrology on a structure is disclosed. The method involves directing an electron beam onto a surface of the structure; capturing a first set of images of the structure at a first landing angle; capturing a second set of images of the structure at a second landing angle, the second landing angle being different from the first landing angle; and determining, by comparing the first set of images to the second set of images, at least one 3D parameter of the structure; wherein the first set of images at the first landing angle and the second set of images at the second landing angle are captured in a single run of the electron beam across the surface of the structure.

In another embodiment of the present disclosure, a method of performing 3D metrology on a structure is disclosed. The method involves defining a main field on at least a portion of a surface of the structure, the structure including at least one array of 3D structures; defining a plurality of subfields within the main field; deflecting an electron beam across each of the plurality of subfields defined within the main field; determining a subfield landing angle in each of the plurality of subfields; capturing a first set of images of the at least one contact hole at a first landing angle, the first landing angle being equal to the subfield landing angle of at least one of the plurality of subfields; capturing a second set of images of the at least one contact hole at a second landing angle, the second landing angle being equal to the subfield landing angle of another one of the at least one the plurality of subfields, such that the second landing angle is different from the first landing angle; and determining, by comparing the first set of images to the second set of images, at least one 3D parameter of the at least one array of 3D structures.

In yet another embodiment still, a method of performing 3D metrology on a structure is disclosed. The method involves defining a main field on at least a portion of a surface of the structure, the structure including at least one array of 3D structures; defining a plurality of subfields within the main field; deflecting an electron beam across each of the plurality of subfields defined within the main field; determining a subfield landing angle in each of the plurality of subfields; capturing a first set of images of the at least one array of 3D structures at a first landing angle, the first landing angle being equal to the subfield landing angle of at least one of the plurality of subfields; capturing a second set of images of the at least one array of 3D structures at a second landing angle, the second landing angle being equal to the subfield landing angle of another one of the at least one the plurality of subfields, such that the second landing angle is different from the first landing angle; determining, by comparing the first set of images to the second set of images, at least one 3D parameter of the at least one array of 3D structures; generating a landing angle distribution map of the subfield landing angle in each of the plurality of subfields; and determining at least one second 3D parameter of a second array of 3D structures formed on a second structure, wherein the at least one second 3D parameter is determined by accessing and referencing the landing angle distribution map.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 is a front view of an exemplary structure on which a 3D metrology process may be performed, according to one or more embodiments shown and described herein;

FIG. 2A is a front view of the structure of FIG. 1 undergoing a beam scan at a first landing angle, according to one or more embodiments shown and described herein;

FIG. 2B is a top view of the structure of FIG. 2A undergoing the beam scan at the first landing angle, according to one or more embodiments shown and described herein;

FIG. 3A is a front view of the structure of FIG. 1 undergoing a beam scan at a second landing angle, according to one or more embodiments shown and described herein;

FIG. 3B is a top view of the structure of FIG. 3A undergoing the beam scan at the second landing angle, according to one or more embodiments shown and described herein;

FIG. 4 is a representative image of a main field of a beam scan, according to one or more embodiments shown and described herein; and

FIG. 5 is a graphic illustration of a landing angle variance of a beam scan across a main field, according to one or more embodiments shown and described herein.

### DETAILED DESCRIPTION

Embodiments disclosed herein relate to methods of performing 3D metrology on a structure. In the embodiments described herein, the term “landing angle” may refer to an angle at which an electron beam (or any other inspection beam) contacts a surface of a structure. It should be further appreciated that, in some embodiments, the landing angle of the electron beam may vary (e.g., via deflection or otherwise) over a scan area analyzed by the electron beam, as will be described in additional detail herein.

In the embodiments described herein, the term “high aspect ratio” (“HAR”) may refer to a structure in which the aspect ratio of the structure exceeds 2.

As noted hereinabove, traditional electron beam processes are generally limited to capturing horizontal (e.g., two-dimensional) measurements of a structure during a single job run. In order to effectively perform 3D metrology, the electron beam must be tilted and/or adjusted over the course of multiple runs, such that a variety of images of the structure at various angles may be captured.

The disclosed method of performing 3D metrology overcomes these limitations by utilizing variance of an electron beam landing angle to achieve 3D metrology in a single job run. For example, the method described herein enables measurements of both 2D and 3D parameters using a single beam condition with varying landing angles. By utilizing the intrinsic landing angle variance within a scan field of the electron beam, the disclosed method may eliminate the need for multiple setup changes (e.g., to the electron beam or a stage on which the sample to be measured may be mounted), thereby reducing measurement time and increasing accuracy.

Moreover, the disclosed method may be implemented in a variety of manners. For example, the landing angle of the electron beam may be varied across a surface of the structure via software control, such that the need for complex mechanical adjustments to the electron beam or stage is alleviated. This flexibility allows for a more efficient and reliable 3D metrology process, which aids in ensuring that all relevant 3D parameters are captured in a single job run.

Embodiments of methods for performing 3D metrology on a structure will now be described in additional detail herein. The following will now describe these methods in more detail with reference to the drawings and where like numbers refer to like structures.

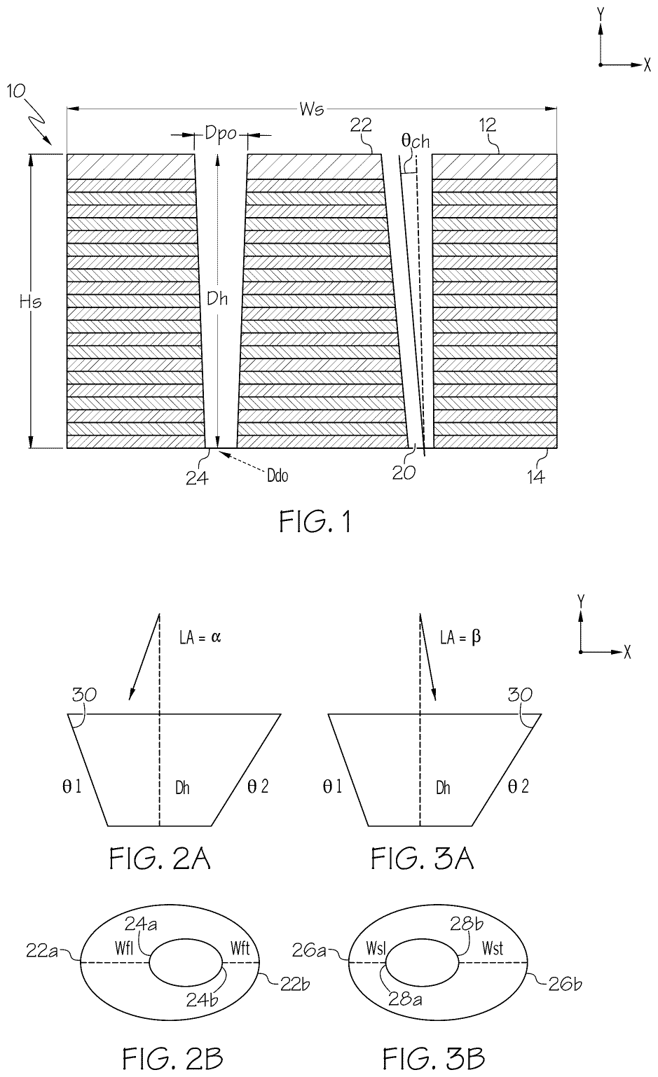

Referring now to FIG. 1, an exemplary structure 10 on which a 3D metrology process may be performed is depicted. In these embodiments, the structure 10 may have a plurality of parameters, such as two-dimensional and three-dimensional parameters which may be ascertained by scanning the structure 10 with an electron beam, or any other similar beam (e.g., laser, etc.) configured to capture scanning electron microscope (“SEM”) images of the structure 10. For example, as depicted in FIG. 1, the structure 10 may have a structure height Hs that may be defined as a distance (e.g., a vertical distance in the +/−y-direction as depicted in the coordinate axis of FIG. 1) between a surface 12 of the structure 10 and a base of the structure 10, and a structure width Ws that extends across a length (e.g., in the +/−x-direction as depicted in the coordinate axis of FIG. 1). In the embodiments described herein, the structure may be a semiconductor chip, semiconductor wafer, or any other similar structure on which a 3D metrology process may be performed.

Furthermore, in the embodiments defined herein, it should be appreciated that the structure 10 may be an HAR structure. As provided herein, the aspect ratio of the structure 10 may be defined as the ratio of the height Hs of the structure 10 relative the width Ws of the structure 10. In other embodiments, and as described herein, the structure may be an etched structure, such that the aspect ratio of the structure 10 may refer to a depth of the structure 10 relative the width Ws of the structure 10.

Referring still to FIG. 1, in these embodiments, the structure 10 may further include a plurality of substructures formed on and/or within the structure 10. In these embodiments, the plurality of substructures may similarly include a plurality of 2D and a plurality of 3D parameters that may be ascertained utilizing the 3D metrology method described herein. In the embodiments described herein, the plurality of substructures may be etched into the structure via reactive ion etching (“RIE”), deep reactive ion etching (“DRIE”), cryogenic deep silicon etching, inductively coupled plasma etching, wet etching, or any other similar process without departing from the scope of the present disclosure. Furthermore, in other embodiments, the plurality of substructures may be formed in a stack extending from the surface 12 and/or the base 14 of the structure 10.

For example, as depicted in FIG. 1, the plurality of substructures may include a plurality of contact holes 20, with each of the plurality of contact holes 20 defining a plurality of two-dimensional and three-dimensional parameters. In these embodiments, each contact hole 20 may extend from the surface 12 of the structure 10 to the base 14 of the structure 10. Although the plurality of contact holes 20 depicted in FIG. 1 are depicted as extending completely through the structure 10 (e.g., such that a height of each of the contact holes 20 is at least equal to the structure height Hs of the structure), it should be further appreciated that, in some embodiments, the plurality of contact holes 20 may extend only partially through the structure 10 (e.g., such that a height of each of the contact holes 20 is less than the structure height Hs of the structure 10).

More particularly, in the embodiments depicted in FIG. 1, each of the plurality of contact holes 20 may include a proximal opening 22 positioned adjacent the surface 12 of the structure 10, and a distal opening 24 positioned opposite the proximal opening 22 and adjacent the base 14 of the structure. In these embodiments, the proximal opening 22 may define a proximal opening diameter Dₚₒ, while the distal opening 24 may define a distal opening diameter D_{do}.

In the embodiments described herein, it should be appreciated that the proximal opening diameter Dₚₒ and the distal opening diameter D_{do} may be two-dimensional parameters that may be determined by sweeping an electron beam across the surface 12 of the structure 10 with a normal landing angle along a particular plane. For example, sweeping the electron beam in a longitudinal direction (e.g., in the +/−x-direction as depicted in the coordinate axis of FIG. 1) with the electron beam positioned normal to the surface 12 of the structure 10 may generate a two-dimensional image of the structure 10, from which the proximal opening diameter Dₚₒ and the distal opening diameter D_{do} of the each of the plurality of contact holes 20 may be ascertained.

However, as further depicted in FIG. 1, the plurality of contact holes 20 may each further include 3D parameters that may not be ascertainable by sweeping the electron beam over the surface 12 of the structure 10 along a particular plane and at a particular landing angle. For example, as depicted in FIG. 1, each of the plurality of contact holes 20 may further define a hole depth Dₕ, which may be defined as a distance (e.g., in the +/−y-direction as depicted in the coordinate axis of FIG. 1) between the proximal opening 22 and the distal opening 24 of each of the plurality of contact holes 20. Furthermore, in the embodiments described herein, and as depicted in FIG. 1, each of the plurality of contact holes 20 may include a pair of sidewalls 30, which may be tilted relative one another such that the contact hole 20 includes a tilt angle Θ_{ch}.

In these embodiments, in order to ascertain the 3D parameters of the plurality of contact holes 20 (e.g., the hole depth Dₕ and the tilt angle Θ_{ch}), the method described herein may obtain multiple sets of images of each of the plurality of holes 20 at various landing angles LA, and compare the multiple sets of images at the various landing angles LA to determine the 3D parameters of each of the contact holes 20.

For example, as depicted in FIGS. 2A and 2B, the method of performing 3D metrology described herein may initially involve obtaining a first set of structure images by conducting a scan of the structure 10 with an electron beam positioned at a first landing angle α. In these embodiments, and as described herein above, it should be understood that the term landing angle may refer to the angle at which the electron beam contacts the surface 12 of the structure 10. Furthermore, in the embodiments described herein, the first landing angle α may be a predetermined first landing angle α. For example, the electron beam may be calibrated such that the first landing angle α is set at a predetermined (e.g., known) value.

Referring still to FIGS. 2A and 2B, the first set of structure images obtained by the initial electron beam scan of the structure 10 may include a front-side view of the contact hole 20 (e.g., FIG. 2A), which illustrates a tilt angle θ1, θ2 of each of the pair of sidewalls 30, and a top-side view of the contact hole 20 (e.g., FIG. 2B), which illustrates the hole depth Dₕ of the contact hole 20. In these embodiments, to determine the hole depth Dh of the contact hole and the tilt angle Θ_{ch} of the contact hole 20, the method described herein may involve calculating a first image distance between various edges of the distal opening 24 and the proximal opening 22 of the contact hole 20 using the first set of structure images obtained by the initial electron beam scan, as will be described in detail herein.

For example, as illustrated in FIG. 2B, the proximal opening 22 displayed in the first set of structure images may further define a first image proximal opening leading edge 22a and a first image proximal opening trailing edge 22b. Similarly, the distal opening 24 displayed in the first set of structure images may further define a first image distal opening leading edge 24a and a first image distal opening trailing edge 24b.

In these embodiments, to determine the 3D parameters of the contact hole 20, the method may further involve determining a first image trailing width W_{ft} and a first image leading width W_{fl}. For example, as depicted in FIG. 2B, the first image leading width W_{fl} may be defined as a distance (e.g., in the longitudinal direction as depicted in the coordinate axis of FIGS. 2A and 2B) between the first image proximal opening leading edge 22a and the first image distal opening leading edge 24a. Similarly, the first image trailing width Wm may be defined as a distance (e.g., in the longitudinal direction as depicted in the coordinate axis of FIGS. 2A and 2B) between the first image proximal opening trailing edge 22b and the first image distal opening trailing edge 24b.

Once the first image trailing width W_{ft} and the first image leading width W_{fl} have been determined, the method may proceed to collect a second set of structure images by conducting a scan of the structure 10 with an electron beam positioned at second landing angle β. In these embodiments, the second landing angle β may be a different angle from the first landing angle α, such that the second set of structure images is distinct from the first set of structure images.

As depicted in FIGS. 3A and 3B, the second set of structure images may similarly include a front side view of the contact hole (e.g., FIG. 3A) and a top-side view of the contact hole 20 (e.g., FIG. 3B). In these embodiments, the proximal opening 22 displayed in the second set of structure images may further define a second image proximal opening leading edge 26a and a second image proximal opening trailing edge 26b. Similarly, the distal opening 24 displayed in the second set of structure images may further define a second image distal opening leading edge 28a and a second image distal opening trailing edge 28b.

In these embodiments, to determine the 3D parameters of the contact hole 20, the method may further involve determining a second image trailing width Wₛₜ and a second image leading width Wₛₗ. It should be appreciated that, in these embodiments, the method for determining the second image trailing width Wₛₜ and the second image leading width Wₛₗ may be the same as the method step conducted to determine the first image trailing width W_{ft} and the first image leading width W_{fl}. For example, as depicted in FIG. 3B, the second image leading width Wₛₗ may be defined as a distance (e.g., in the longitudinal direction as depicted in the coordinate axis of FIGS. 3A and 3B) between the second image proximal opening leading edge 26a and the second image distal opening leading edge 28a. Similarly, the second image trailing width Wₛₜ may be defined as a distance (e.g., in the longitudinal direction as depicted in the coordinate axis of FIGS. 3A and 3B) between the second image proximal opening trailing edge 26b and the second image distal opening trailing edge 28b.

Referring now to FIGS. 2A-3B collectively, once the first image trailing width, the first image leading width, the second image trailing width, and the second image trailing width have been determined, the method may proceed to calculate the 3D parameters of the contact hole 20 (e.g., hole depth Dₕ and tilt angle θ1, θ2 of each of the pair of sidewalls 30. In these embodiments, the 3D parameters may be determined using the following equations:

$$D h = \frac{( Wfl - Wsl )}{tan ( α ) - tan ( β )} \\ θ1 = arctan ( \frac{Wsl tan ( α ) - Wfl tan ( β )}{Wfl - Wsl} ) \\ θ2 = arctan ( \frac{Wst tan ( α ) - Wft tan ( β )}{Wft - Wst} )$$

As should appreciated in view of the foregoing, the various 3D parameters of each of the plurality of contact holes 20 formed on the structure 10 may be determined by obtaining a first set of images at a first landing angle and a second set of images at a second angle different from the first landing angle, and analyzing the obtained first set of images and second set of images to determine the relevant 3D parameters.

Furthermore, while any distinction between the first landing angle α and the second landing angle β (e.g., in degrees) may allow the 3D parameters of the contact hole 20 to be determined, it should be further understood that the accuracy of the calculated 3D parameters, and the ease with which the 3D parameters may be calculated, may be proportional to the difference between the first landing angle α and the second landing angle β. For example, in the embodiments described herein, the 3D parameters of the contact hole 20 are a function of the first landing angle α and the second landing angle β, such that providing a larger difference between the first landing a and the second landing angle β may provide more distinguishable information regarding the 3D parameters of the contact hole 20. Accordingly, by increasing the difference between the first landing angle α and the second landing angle β, uncertainties regarding hole depth Dₕ may be minimized and/or eliminated, while accuracy of the tilt angle θ1, θ2 measurements may be similarly improved.

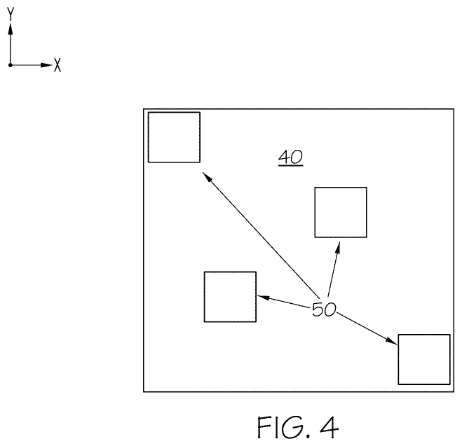

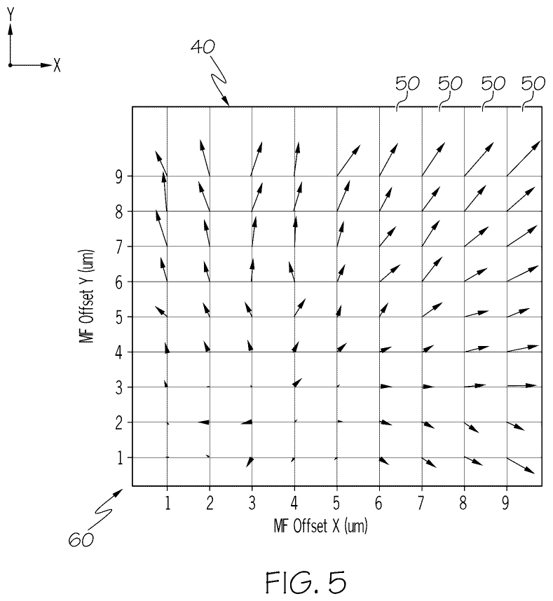

Referring now to FIGS. 4 and 5, it should be further appreciated that, in the method of performing 3D metrology described herein, the method may obtain the first set of images at the first landing angle α and the second set of images at the second landing angle β in a single scan of the structure 10. That is, the method of performing 3D metrology may obtain the first set of images and the second set of images (e.g., at two different landing angles) using the built-in landing angle variation of the electron beam by deflecting the beam from one scan area to another within a finite range without manipulating a stage on which the electron beam may be disposed, and/or moving the structure 10 itself.

To obtain the first set of images at the first landing angle α and the second set of images at the second landing angle β without manipulating the electron beam or the structure 10, the method may further involve defining a main field 40 on at least a portion of the surface 12 of the structure 10. For example, in these embodiments, the main field 40 may be defined as a region of the surface 12 of the structure 10 which the electron beam may be capable of scanning in a single pass within 40 without needing to manipulate the electron beam and/or the structure 10. Accordingly, it should be appreciated that, by limiting the main field 40 to an area which the electron beam is capable of scanning in a single pass, the method may alleviate timeliness issues and inaccuracies that may result from manipulation of the electron beam and/or structure 10 between multiple scans.

As depicted in FIGS. 4 and 5, the main field 40 may define an area of up to 100 micrometers (μm) on the surface 12 of the structure 10. However, it should be appreciated that the main field 40 may define an area of any size without departing from the scope of the present disclosure.

Referring still to FIGS. 4 and 5, the method may further involve defining a plurality of subfields 50 within the main field 40. In these embodiments, each of the plurality of subfields 50 may be defined as a subsection of the main field 40, with each of the plurality of subfields 50 defining at least a portion of the main field 40. For example, each of the plurality of subfields 50 may have an equal subfield area, such that the plurality of subfields 50 form a grid within the main field 40. Although each of the plurality of subfields 50 in FIGS. 4 and 5 are each depicted as having an equal subfield area, it should be further appreciated that, in other embodiments, the plurality of subfields 50 may have different subfield areas without departing from the scope of the present disclosure.

Referring still to FIGS. 4 and 5, in operation, the method may initially involve defining the main field 40 and the plurality of subfields 50 within the main field 40. With the main field 40 and the plurality of subfields 50 defined, the electron beam scan may be performed. In these embodiments, the electron beam may be deflected across the main field 40 to access different subfields of the plurality of subfields 50 to perform scanning on these individual subfields sequentially.

In these embodiments, the electron beam may be deflected across the main field 40 until each of the plurality of subfields 50 have been scanned. As illustrated most clearly in FIG. 5, the deflection of the electron beam as the electron beam is scanned across the main field 40 may result in the electron beam having a distinct landing angle in each of the plurality of subfields 50. For example, in these embodiments, it should be appreciated that, as the electron beam deflects between each of the plurality of subfields 50, the landing angle of the electron beam within each of the plurality of subfields 50 may change, such that the landing angle in each of the plurality of subfields 50 is distinct. Accordingly, by defining a main field 40 on the surface 12 of the structure 10 and defining a plurality of subfields 50 within the main field 40, it may be possible to obtain a first image set having a first landing angle α and a second image set having a second landing angle β, as each of the plurality of subfields 50 analyzed by the electron beam include a different landing angle. Since in practical situations, the 3D array features of structure 10 share the same shapes and dimensions within main field 40, the set of images obtained in scanned subfields 50 can be considered as multiple scans over a same location with different landing angle. As a result, the 3D parameters of the contact hole 20 of the structure 10 (e.g., as described herein with reference to FIGS. 2A-3B) may be determined based on a single scan of a main field 40 of the structure 10.

Referring now to FIG. 5, the scan of the main field 40 of the structure 10 may generate a landing angle distribution chart 60, which may depict the landing angle of the electron beam in each of the plurality of subfields 50 defined in the main field 40. In these embodiments, the method may further involve storing the landing angle distribution chart 60 in a computer (not depicted) or other software device. In these embodiments, the landing angle distribution chart 60 may be accessed and reference to determined 3D parameters of subsequent structures scanned with the electron beam.

Although the method of performing 3D metrology described herein includes a definition of the main field 40 and the plurality of subfields 50 which utilize the deflection of the electron beam to generate the landing angle distribution chart 60, it should be further appreciated that the method is not limited to such embodiments. For example, in other embodiments, the method of performing 3D metrology described herein may be similarly implemented by actively changing the landing angle of the electron beam as the electron beam scans the surface 12 of the structure 10, such as through a software controller (e.g., microcontroller, etc.) or other similar control mechanism. In embodiments in which the landing angle of the electron beam is controlled via a control mechanism, it should be understood that the method described herein may be conducted without deflection of the electron beam.

In view of the foregoing, it should be appreciated that the embodiments described herein are related to a method of performing 3D metrology on a structure. For example, as described in detail herein, the method may involve directing an electron beam onto a surface of the structure, with the structure including at least one contact hole formed in the structure and extending between the surface of the structure and a base of the structure. The method may further involve capturing a first set of images of the at least one contact hole at a first landing angle, and capturing a second set of images of the at least one contact hole at a second landing angle, with the second landing angle being different from the first landing angle. Once the first set of images and the second set of images have been captured, the method may involve determining, by comparing the first set of images to the second set of images, at least one 3D parameter of the at least one contact hole. In these embodiments, it should be appreciated that the first set of images at the first landing angle and the second set of images at the second landing angle may be captured in a single run of the electron beam across the surface of the structure, which may reduce the time required to determine the 3D parameters of the contact hole of the structure while also increasing the accuracy of the measurements of the 3D parameters.

The embodiments disclosed herein may be further described with reference to the following aspects:

According to one aspect of the disclosure, and potentially in combination with other disclosed aspects of the disclosure, a method of performing 3D metrology on a structure includes directing an electron beam onto a surface of the structure; capturing a first set of images of the structure at a first landing angle; capturing a second set of images of the structure at a second landing angle, the second landing angle being different from the first landing angle; and determining, by comparing the first set of images to the second set of images, at least one 3D parameter of the structure; wherein the first set of images at the first landing angle and the second set of images at the second landing angle are captured in a single run of the electron beam across the surface of the structure.

According to one aspect of the disclosure, and potentially in combination with other disclosed aspects of the disclosure, the first set of images at the first landing angle and the second set of images at the second landing angle are further captured without manipulating the structure.

According to one aspect of the disclosure, and potentially in combination with other disclosed aspects of the disclosure, prior to capturing the first set of images, the method further comprises defining a main field on at least a portion of the surface of the structure.

According to one aspect of the disclosure, and potentially in combination with other disclosed aspects of the disclosure, the method further comprises defining a plurality of subfields within the main field.

According to one aspect of the disclosure, and potentially in combination with other disclosed aspects of the disclosure, the method further comprises deflecting the electron beam across each of the plurality of subfields defined within the main field.

According to one aspect of the disclosure, and potentially in combination with other disclosed aspects of the disclosure, the method further comprises determining a subfield landing angle in each of the plurality of subfields.

According to one aspect of the disclosure, and potentially in combination with other disclosed aspects of the disclosure, the method further comprises generating a landing angle distribution map of the subfield landing angle in each of the plurality of subfields.

According to one aspect of the disclosure, and potentially in combination with other disclosed aspects of the disclosure, the first landing angle is at least one of the subfield landing angles and the second landing angle is at least another one of the subfield landing angles.

According to one aspect of the disclosure, and potentially in combination with other disclosed aspects of the disclosure, the method further comprises storing the landing angle distribution map in a computer device.

According to one aspect of the disclosure, and potentially in combination with other disclosed aspects of the disclosure, the method further comprises determining at least one second 3D parameter of a second structure, wherein the at least one second 3D parameter is determined by accessing and referencing the landing angle distribution map.

According to one aspect of the disclosure, and potentially in combination with other disclosed aspects of the disclosure, the at least one 3D parameter is at least one of a depth of at least one contact hole formed in the structure or a tilt angle of a pair of sidewalls formed in the at least one contact hole.

According to one aspect of the disclosure, and potentially in combination with other disclosed aspects of the disclosure, the structure is a high aspect ratio structure.

According to one aspect of the disclosure, and potentially in combination with other disclosed aspects of the disclosure, the method further comprises adjusting the electron beam between the first landing angle and the second landing angle using a control mechanism.

According to one aspect of the disclosure, and potentially in combination with other disclosed aspects of the disclosure, a method of performing 3D metrology on a structure includes defining a main field on at least a portion of a surface of the structure, the structure including at least one array of 3D structures; defining a plurality of subfields within the main field; deflecting an electron beam across each of the plurality of subfields defined within the main field; determining a subfield landing angle in each of the plurality of subfields; capturing a first set of images of the at least one contact hole at a first landing angle, the first landing angle being equal to the subfield landing angle of at least one of the plurality of subfields; capturing a second set of images of the at least one contact hole at a second landing angle, the second landing angle being equal to the subfield landing angle of another one of the at least one the plurality of subfields, such that the second landing angle is different from the first landing angle; and determining, by comparing the first set of images to the second set of images, at least one 3D parameter of the at least one array of 3D structures.

According to one aspect of the disclosure, and potentially in combination with other disclosed aspects of the disclosure, the first set of images at the first landing angle and the second set of images at the second landing angle are captured in a single run of the electron beam across the main field of the structure.

According to one aspect of the disclosure, and potentially in combination with other disclosed aspects of the disclosure, the first set of images at the first landing angle and the second set of images at the second landing angle are further captured without manipulating the structure.

According to one aspect of the disclosure, and potentially in combination with other disclosed aspects of the disclosure, the method further comprises generating a landing angle distribution map of the subfield landing angle in each of the plurality of subfields.

According to one aspect of the disclosure, and potentially in combination with other disclosed aspects of the disclosure, the structure is a high aspect ratio structure.

According to one aspect of the disclosure, and potentially in combination with other disclosed aspects of the disclosure, the at least one 3D parameter is at least one of a depth of the array of 3D structures or a tilt angle of a pair of sidewalls formed in the at least one array of 3D structures.

According to one aspect of the disclosure, and potentially in combination with other disclosed aspects of the disclosure, a method of performing 3D metrology on a structure includes defining a main field on at least a portion of a surface of the structure, the structure including at least one array of 3D structures; defining a plurality of subfields within the main field; deflecting an electron beam across each of the plurality of subfields defined within the main field; determining a subfield landing angle in each of the plurality of subfields; capturing a first set of images of the at least one array of 3D structures at a first landing angle, the first landing angle being equal to the subfield landing angle of at least one of the plurality of subfields; capturing a second set of images of the at least one array of 3D structures at a second landing angle, the second landing angle being equal to the subfield landing angle of another one of the at least one the plurality of subfields, such that the second landing angle is different from the first landing angle; determining, by comparing the first set of images to the second set of images, at least one 3D parameter of the at least one array of 3D structures; generating a landing angle distribution map of the subfield landing angle in each of the plurality of subfields; and determining at least one second 3D parameter of a second array of 3D structures formed on a second structure, wherein the at least one second 3D parameter is determined by accessing and referencing the landing angle distribution map.

The terminology used herein is for the purpose of describing particular aspects only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “or a combination thereof” means a combination including at least one of the foregoing elements.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method of performing 3D metrology on a structure, the method comprising:
directing an electron beam onto a surface of the structure;
capturing a first set of images of the structure at a first landing angle;
capturing a second set of images of the structure at a second landing angle, the second landing angle being different from the first landing angle; and
determining, by comparing the first set of images to the second set of images, at least one 3D parameter of the structure;
wherein the first set of images at the first landing angle and the second set of images at the second landing angle are captured in a single run of the electron beam across the surface of the structure.

2. The method of claim 1, wherein the first set of images at the first landing angle and the second set of images at the second landing angle are further captured without manipulating the structure.

3. The method of claim 1, prior to capturing the first set of images, the method further comprises defining a main field on at least a portion of the surface of the structure.

4. The method of claim 3, further comprising defining a plurality of subfields within the main field.

5. The method of claim 4, further comprising deflecting the electron beam across each of the plurality of subfields defined within the main field.

6. The method of claim 5, further comprising determining a subfield landing angle in each of the plurality of subfields.

7. The method of claim 6, further comprising generating a landing angle distribution map of the subfield landing angle in each of the plurality of subfields.

8. The method of claim 7, wherein the first landing angle is at least one of the subfield landing angles and the second landing angle is at least another one of the subfield landing angles.

9. The method of claim 7, further comprising storing the landing angle distribution map in a computer device.

10. The method of claim 9, further comprising determining at least one second 3D parameter of a second structure, wherein the at least one second 3D parameter is determined by accessing and referencing the landing angle distribution map.

11. The method of claim 1, wherein the at least one 3D parameter is at least one of a depth of at least one contact hole formed in the structure or a tilt angle of a pair of sidewalls formed in the at least one contact hole.

12. The method of claim 1, wherein the structure is a high aspect ratio structure.

13. The method of claim 1, further comprising adjusting the electron beam between the first landing angle and the second landing angle using a control mechanism.

14. A method of performing 3D metrology on a structure, the method comprising:
defining a main field on at least a portion of a surface of the structure, the structure including at least one array of 3D structures;
defining a plurality of subfields within the main field;
deflecting an electron beam across each of the plurality of subfields defined within the main field;
determining a subfield landing angle in each of the plurality of subfields;
capturing a first set of images of the at least one contact hole at a first landing angle, the first landing angle being equal to the subfield landing angle of at least one of the plurality of subfields;
capturing a second set of images of the at least one contact hole at a second landing angle, the second landing angle being equal to the subfield landing angle of another one of the at least one the plurality of subfields, such that the second landing angle is different from the first landing angle; and
determining, by comparing the first set of images to the second set of images, at least one 3D parameter of the at least one array of 3D structures.

15. The method of claim 14, wherein the first set of images at the first landing angle and the second set of images at the second landing angle are captured in a single run of the electron beam across the main field of the structure.

16. The method of claim 14, wherein the first set of images at the first landing angle and the second set of images at the second landing angle are further captured without manipulating the structure.

17. The method of claim 14, further comprising generating a landing angle distribution map of the subfield landing angle in each of the plurality of subfields.

18. The method of claim 14, wherein the structure is a high aspect ratio structure.

19. The method of claim 14, wherein the at least one 3D parameter is at least one of a depth of the array of 3D structures or a tilt angle of a pair of sidewalls formed in the at least one array of 3D structures.

20. A method of performing 3D metrology on a structure, the method comprising:
defining a main field on at least a portion of a surface of the structure, the structure including at least one array of 3D structures;
defining a plurality of subfields within the main field;
deflecting an electron beam across each of the plurality of subfields defined within the main field;
determining a subfield landing angle in each of the plurality of subfields;
capturing a first set of images of the at least one array of 3D structures at a first landing angle, the first landing angle being equal to the subfield landing angle of at least one of the plurality of subfields;
capturing a second set of images of the at least one array of 3D structures at a second landing angle, the second landing angle being equal to the subfield landing angle of another one of the at least one the plurality of subfields, such that the second landing angle is different from the first landing angle;
determining, by comparing the first set of images to the second set of images, at least one 3D parameter of the at least one array of 3D structures;
generating a landing angle distribution map of the subfield landing angle in each of the plurality of subfields; and
determining at least one second 3D parameter of a second array of 3D structures formed on a second structure, wherein the at least one second 3D parameter is determined by accessing and referencing the landing angle distribution map.
